(19) United States
(12) Patent Application Publication
(10) Pub. No.: US 2011/0143539 A1
(43) Pub. Date: Jun. 16, 2011

(54) POLISHING PAD WITH ENDPOINT WINDOW AND SYSTEMS AND METHODS USING THE SAME

(76) Inventors: Rajeev Bajaj, Fremont, CA (US); Stephen Mark Fisher, San Jose, CA (US); William D. Joseph, Maplewood, MN (US)

(21) Appl. No.: 12/991,097

(22) PCT Filed: May 15, 2009
(86) PCT No.: PCT/US2009/044187

§ 371 Date: Feb. 28, 2011

Related U.S. Application Data
(60) Provisional application No. 61/053,429, filed on May 15, 2008.

(51) Int. Cl. H01L 21/306; B24B 41/00

(52) U.S. Cl. 438/692; 451/442; 257/E21.23

(57) ABSTRACT

A polishing pad including a path therethrough to transmit a signal for in situ monitoring of an endpoint in a polishing operation. In one embodiment, the polishing pad includes a polishing composition distribution layer on a first side of a guide plate and a support layer on an opposed second side of a guide plate. The guide plate retains a plurality of polishing elements that extend along a first direction substantially normal to a plane including the polishing pad and through the polishing composition distribution layer. The polishing pad includes an optical path along the first direction and through a thickness of the pad.

### TECHNICAL FIELD

The present disclosure relates to polishing pads with projecting polishing elements and a path through the thickness of the pad that makes possible the transmission of a monitoring signal for in situ determination of an endpoint in a polishing process.

### BACKGROUND

During the manufacture of semiconductor integrated circuits, silicon wafers are iteratively processed through a series of deposition and etching cycles to form overlying material layers and structures. A polishing technique called chemical mechanical planarization (CMP) may be used to remove surface irregularities remaining after the deposition and etching steps, such as bumps, areas of unequal elevation, troughs, and trenches. In a chemical mechanical planarization process a substrate is pressed against and rotated with respect to a polishing pad in the presence of a polishing composition with abrasive and/or etching chemistry, typically a slurry.

During the planarization process, it is desirable to detect when the desired surface planarity or layer thickness has been reached and/or when an underlying layer has been exposed to determine when to stop polishing. For example, a deposited material can be removed from the substrate to a predetermined level and then the polishing process stopped via endpoint detection, a timed process or some other physical or chemical technique. In one endpoint detection technique, an optical monitoring system can be used for in situ measuring of the uniformity of a layer on a substrate. The optical monitoring system can include a radiation source that directs a beam of energy toward the substrate during polishing, a detector that measures the radiation reflected from the substrate, and a computer that analyzes a signal from the detector and calculates whether the endpoint has been detected.

In some chemical mechanical polishing systems, a light beam is directed toward the substrate through an open aperture in a polishing surface of the polishing pad, or through a transparent window member placed in the aperture in the polishing surface.

### SUMMARY

In general, the present disclosure is directed to a polishing pad including a path therethrough to transmit a signal for in situ monitoring of an endpoint in a polishing operation.

In some embodiments, the path has a minimal impact on the polishing zone of the polishing pad (the surfaces of the polishing pad in contact with and/or responsible for abrading the substrate). The polishing zone is free of large apertures, transparent windows or other areas that can cause inconsistent polishing, pooling of polishing composition, or fouling with polishing composition. Transmission of the monitoring signal with minimal impact on the polishing zone can provide consistently accurate transmission of the monitoring signal without substantially compromising polishing performance.

In some embodiments, since the path does not require removal of material from the polishing zone, compared to conventional designs the transmission function of the path is more effectively decoupled from the polishing function of the pad. This decoupling can provide improved polishing and signal monitoring performance.

In some embodiments, the polishing pad described in this disclosure provides some or all of the following advantages. For example, in some embodiments, an aperture and/or a transparent member is provided in a support layer of the pad, away from the polishing zone. Placing the aperture/transparent member away from the polishing zone can prevent a polishing composition from entering the aperture, which reduces aperture fouling and abrasion of the transparent member. Placing the aperture/transparent member away from the polishing zone keeps the polishing composition away from the underside of the polishing pad and away from adhesives that can be used to hold the transparent member in position, which can extend the service life of the pad and the adhesive.

Since the transparent member does not come into contact with the polishing composition, the material from which the transparent member is made can be selected to more effectively transmit the monitoring signal without substantial regard to its resistance to wear from repeated exposure to the polishing composition. Since the transparent member does not wear prematurely from repeated exposure to polishing composition, the transparent member can maintain more consistent signal transmission properties over the service life of the polishing pad.

In one embodiment, the present disclosure is directed to a polishing pad including a polishing composition distribution layer on a first side of a guide plate and a support layer on an opposed second side of a guide plate. The guide plate retains a plurality of polishing elements that extend along a first direction substantially normal to a plane including the polishing pad and through the polishing composition distribution layer. The polishing pad includes an optical path along the first direction and through a thickness of the pad for transmitting a signal for in situ monitoring of an endpoint in a polishing operation.

In another embodiment, the present disclosure is directed to a polishing pad, including a polishing composition distribution layer on a first major surface of a transparent guide plate. The guide plate retains a plurality of polishing elements that extend along a first direction substantially normal to a plane including the polishing pad and through the polishing composition distribution layer. A first region in the polishing composition distribution layer is free of polishing elements. A support layer resides on the second major surface of the guide plate, and the support layer includes a transparent region underlying the first region.

In another embodiment, the disclosure is directed to a polishing pad including a polishing composition distribution layer with a plurality of polishing elements. The polishing elements extend upwardly through the polishing composition distribution layer. The polishing composition distribution layer includes a first region with at least one transparent polishing element. A support layer with a transparent region underlies the first region.

In yet another embodiment, the present disclosure is directed to a chemical mechanical polishing system including a platen and a polishing pad on the platen. The polishing pad includes a polishing composition distribution layer on a first major surface of a guide plate, wherein the guide plate retains a plurality of polishing elements that extend through the polishing composition distribution layer, and a support layer on a second major surface of the guide plate. The system further includes a means for transmitting a monitoring signal through the polishing pad; and a monitoring system to monitor a polishing operation, wherein the monitoring system emits a monitoring signal through the means for transmitting to a detector.

In yet another embodiment, the present disclosure is directed to a method including providing a chemical mechanical polishing apparatus with a monitoring system. The monitoring system emits a monitoring signal for monitoring a polishing operation and a detector for detecting the monitoring signal. The method further includes providing a polishing pad including a polishing composition distribution layer with a plurality of polishing elements that extend through the polishing composition distribution layer, and a support layer underlying the polishing composition distribution layer. The method further includes transmitting the monitoring signal from the source to the detector through a path in the polishing pad, wherein the path includes a transparent region in the support layer and a first region in the polishing composition distribution layer at least partially aligned with the transparent region. The first region includes one of a region free of polishing elements, or a region with at least one transparent polishing element.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a schematic cross-sectional view of a chemical mechanical polishing (CMP) apparatus utilizing the polishing pads described herein.

FIG. 2 is a schematic, cross-sectional view of a portion of a polishing pad including a polishing element.

FIG. 3 is a schematic top view of a polishing pad with a region including an optical path.

FIG. 4 is a cross-sectional view of an embodiment of a polishing pad with an optical path including a first aperture in a polishing composition distribution layer at least partially overlying a second aperture in a support layer.

FIG. 5 is a cross-sectional view of the polishing pad of FIG. 4, wherein the optical path includes a transparent plug in the second aperture.

FIG. 6 is a cross-sectional view of the polishing pad of FIG. 4, wherein the aperture in the support layer is at least partially sealed with a layer of an adhesive.

FIG. 7 is a cross-sectional view of an embodiment of a polishing pad with an optical path including a first aperture in a polishing composition distribution layer at least partially overlying a transparent region in a support layer.

FIG. 8 is a cross-sectional view of an embodiment of a polishing pad with an optical path including a transparent polishing element at least partially overlying a transparent region in a support layer.

Like reference numerals in the drawings indicate like elements. The drawings herein as not to scale, and in the drawings the components of the polishing pads are sized to emphasize selected features.

### DETAILED DESCRIPTION

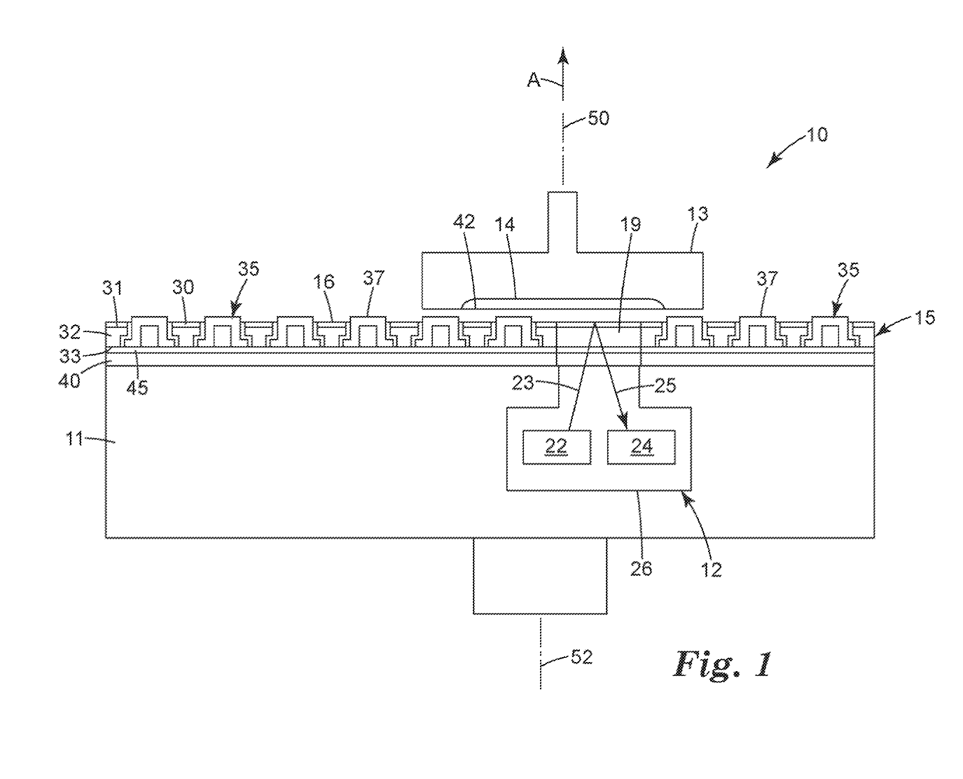

As shown in FIG. 1, a chemical mechanical polishing apparatus 10 includes a polishing pad 15 disposed on a platen 11. The platen 11 includes an endpoint monitoring system 12. The endpoint monitoring system 12 may vary widely depending on the intended application, and may include systems utilizing a wide variety of monitoring signals. Examples include single or multi-wavelength monitoring signals, systems utilizing reflectometry or interferometry. For example, the monitoring system 12 can include an optical sensor, an eddy current sensor, a capacitance sensor and the like.

In the embodiment shown in FIG. 1, the endpoint monitoring system 12 is an optical system that includes a light source 22 (e.g., a laser, such as a red laser, a blue laser, or an infrared laser, or a light emitting diode, such as a red light emitting diode, a blue light emitting diode, or an infrared light emitting diode) and a light detector 24 (e.g., a photodetector). In this embodiment, the optical monitoring system 12 is housed in a recess 26 in platen 11, although such an arrangement is not required.

The apparatus 10 also includes a polishing head 13 that holds a substrate 14 (e.g., a semiconductor wafer, optionally coated with one or more dielectric, conductive or semiconductive layers). The endpoint monitoring system 12 monitors polishing of substrate 14 via an optical path 19 traversing the thickness of the polishing pad 15—i.e. along a direction A generally normal to a plane including the pad. The pad 15 includes a polishing composition distribution layer 30 on a first side 31 of a guide plate 32. The guide plate 32 retains an arrangement of elongate polishing elements 35, which project upwardly through the polishing composition distribution layer 30. The polishing elements 35 can have a wide variety of shapes, but generally the elements 35 are elongate bodies with a longitudinal axis generally along direction A. The polishing pad 15 further includes a support layer 40 on a second side 33 of the guide plate 32.

The optical path 19, which is shown schematically in FIG. 1, will be described in more detail below, and may include one or more apertures, material layers, and/or polishing elements 35 that are collectively substantially transparent to energy or fields in the range of wavelength(s) of interest utilized by the endpoint monitoring system 12. In this application, the term transparent means that at least about 25% (e.g., at least about 35%, at least about 50%, at least about 60%, at least about 70%, at least about 80%, at least about 90%, at least about 95%) of energy at a wavelength of interest that enters the optical path 19 is transmitted through the polishing pad 15 along the path 19.

In general, during use of apparatus 10 in a CMP process, a chemical polishing composition (e.g., a slurry containing one or more chemical agents and optionally abrasive particles) is applied to a surface 16 of the polishing composition distribution layer 30. The chemical polishing composition is applied to the polishing pad 15 as platen 11, polishing pad 15 and endpoint monitoring system 22 rotate about an axis 52. The polishing head 13 is lowered so that a surface 42 of substrate 14 comes into contact with the tips 37 of the polishing elements 35. While the polishing composition distribution layer 30 distributes the polishing composition on the substrate and the polishing elements 35, the polishing head 13 and the substrate 14 are rotated about an axis 50 and cause the polishing tips 37 to translate laterally across the polishing pad 15 and remove material from the substrate 14. The light source 22 directs a light beam 23 at the surface 42, and the light detector 24 measures the light beam 25 that is reflected from substrate 42 (e.g., from surface 42 and/or the surface of one or more underlying layers in substrate 42).

In the embodiment shown in FIG. 1, the wavelength(s) of light in beam 23 and/or 25 can vary depending upon the property being detected. As an example, the wavelength(s) of interest can span the visible spectrum (e.g., from about 400 nm to about 800 nm). As another example, the wavelength(s) of interest can be within a certain portion of the visible spectrum (e.g., from about 400 nm to about 450 nm, from about 650 nm to about 800 nm). As an additional example, the wavelength(s) of interest may be outside the visible portion of the spectrum (e.g., ultraviolet (such as from about 300 nm to about 400 nm), infrared (such as from about 800 nm to about 1550 nm)).

The information collected by the detector 24 is processed to determine whether the polishing endpoint has been reached. For example, a computer (not shown in FIG. 1) can receive the measured light intensity from the detector 24 and evaluate the resulting signal to determine the polishing endpoint (e.g., by detecting a sudden change in the reflectivity of substrate 42 that indicates the exposure of a new layer, by calculating the thickness removed from the outer layer (such as a transparent oxide layer) of substrate 42 using interferometric principles, and/or by monitoring the signal for predetermined endpoint criteria.

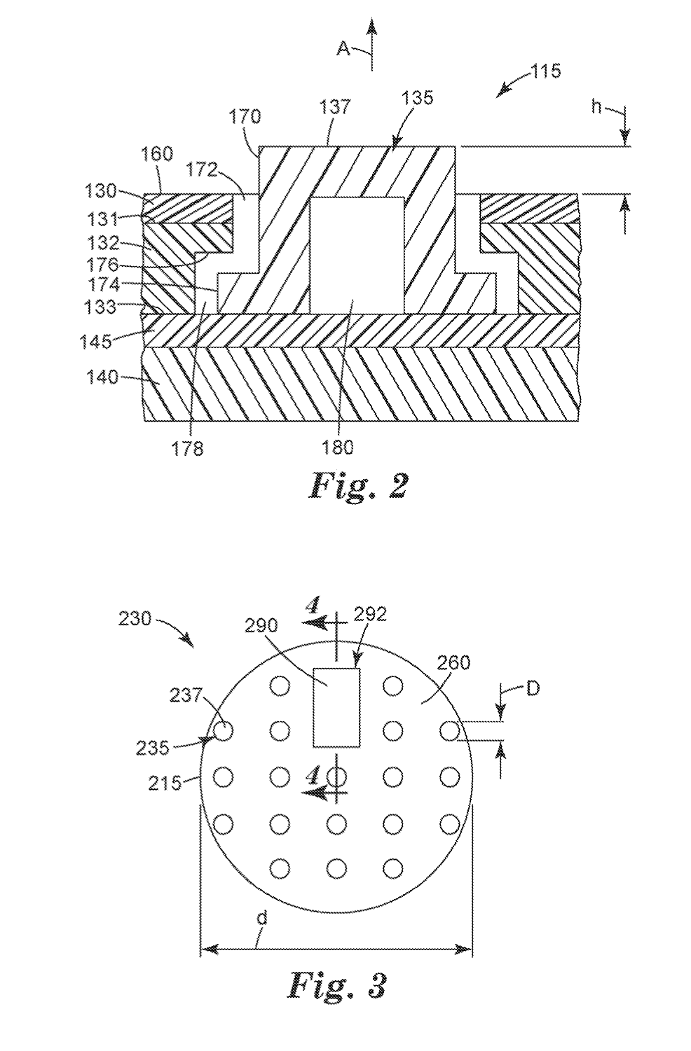

FIG. 2 shows a cross sectional view of an individual elongate polishing element 135 in a polishing pad 115. In the embodiment shown in FIG. 2, the polishing element 135 is retained by a guide plate 132 and projects upwardly through a polishing composition distribution layer 130. The polishing element 135 includes a polishing tip 137, which may make sliding or rolling contact with a substrate to be polished. For example, the polishing tip 137 may be a substantially flat surface or a rolling tip. Prior to the first use of the polishing pad in a polishing operation, the height h of the polishing tip 135 is at least about 0.25 mm to about 3.0 mm above the upper surface 160 of the polishing composition distribution layer 130, and in some embodiments h may be 0.5 mm, 1.5 mm, 2.0 mm, 2.5 mm, 3.0 mm or more, depending on the polishing composition used and the material selected for the polishing element 135.

The polishing element 135 includes an elongate main body 170 with a longitudinal axis generally along direction A. The elongate body 170 resides in a main bore 172, which extends through the polishing composition distribution layer 130 and the guide plate 132. The polishing element 135 further includes at least one flange 174 extending outward from the body 170, which engages a shoulder 176 formed by an undercut region 178 in the main bore 172 in the guide plate 132. In the embodiment shown in FIG. 2, the polishing element 135 includes a core region 180, although such an arrangement is not required.

In some embodiments, the polishing element 135 rests on a first major surface 133 of a support layer 140, and may optionally be attached to the surface 133 by a layer of a preferably transparent adhesive (not shown in FIG. 2), such as double sided tape or epoxy. Thus, the polishing elements 135 are free to independently move in a vertical direction along their longitudinal axis A, through the main bore 172 in the guide plate 132 and the polishing composition distribution layer 130.

The cross-sectional shape of the elongate main body 170 of the polishing element 135 may vary widely depending on the intended application. For example, circular, triangular, and trapezoidal cross sectional shapes have been found to be useful. For example, the polishing pad 215 in FIG. 3 includes polishing elements 235 with a circular cross sectional shape, which provides a polishing element with a substantially cylindrical main body. The polishing tip 237 is also substantially circular in this embodiment, and has a diameter D of at least about 50 μm. In some embodiments, the diameter D of the polishing tip 237 is about 50 μm to about 20 mm, in some embodiments the diameter D is about 5 mm to about 15 mm, and in other embodiments the diameter D is about 12 mm to about 15 mm.

The polishing elements 235 may be arranged on a surface 260 of the polishing composition distribution layer 230 in a wide variety of patterns, depending on the intended application, and the patterns may be regular or irregular. The polishing elements 235 may cover substantially the entire surface 260, or there may be regions 292 of the surface 260 that include no polishing elements 235. In some embodiments, the polishing elements have an average density between about 30 and about 80 percent of the total area of the surface 260, as determined by the diameter D of each polishing element 235 and the diameter d of the polishing pad 215.

Referring again to FIG. 2, the depth and spacing of the bores 172 throughout the guide plate 132 may be varied as necessary for a specific CMP process. The polishing elements 135 are each maintained in planar orientation with respect to one other and the guide plate 132, and project above the surface of the polishing composition distribution layer 130. The volume created by the polishing elements 135 above the guide plate 132 and the polishing composition distribution layer 130 provides room for distribution of a polishing composition on the surface 160 of the polishing composition distribution layer 130. The polishing elements 135 protrude above the polishing composition distribution layer 130 by an amount that depends at least in part on the material characteristics of the polishing elements 135 and the desired flow of polishing composition (preferably a slurry) over the surface 160.

The polishing elements 135 may be made of a wide variety of materials, including, for example, metals, ceramics, polymeric materials and combinations thereof. Suitable polymeric materials include polyurethanes, polyesters, polycarbonates, and acetals available under the trade designation DELRIN from E.I. DuPont de Nemours, Inc., Wilmington, Del. Any of these materials may be made transparent to the wavelength of interest in the endpoint monitoring system 12 (FIG. 1). In other embodiments, any of these materials, whether transparent or not, may be made electrically and/or thermally conductive by including therein fillers such as, carbon, graphite, metals or combinations thereof. In other embodiments, electrically conductive polymers such as, for example, polyanilines (PANI) available under the trade designation ORMECOM from Ormecon Chemie, Ammersbek, Germany, may be used, with or without the electrically or thermally conductive fillers referred to above.

While the elongate body 170, the polishing tip 137 and the core 180 of the polishing element 135 can be made of the same material, such an arrangement is not required, and these portions of the polishing element 135 can be the same or different materials as necessary for a particular application. For example, in some embodiments the core 180 and/or the body 170 can be made of conductive materials and separated by an insulating material. In some embodiments, as described in WO/2006/055720, incorporated herein by reference, the core 180 of the polishing element 135 can include sensors to detect pressure, conductivity, capacitance, eddy currents, and the like. In yet another embodiment, the body 170 of the polishing element 135, which is made of a first material, can be encased in a second and different material to, for example, enable signal transmission through the optical element 135. In this arrangement, the second material does not take part in polishing operations.

Referring again to FIG. 2, in some embodiments the guide plate 132 can provide lateral support for the polishing elements 135 and allow the elements 135 to move independently along direction A. The guide plate 132 includes the polishing composition distribution layer 130 on its first side, preferably on its first major surface 131, and a support layer 140 on its second side, preferably on its second major surface 133. The guide plate may further include an optional liquid impermeable membrane layer 145 on its second major surface 133 to control leakage of liquid polishing compositions.

The guide plate 132 can be made of a wide variety of materials, but a non-conducting and liquid impermeable polymeric material is preferred, and polycarbonates have been found to be particularly useful. The polymeric material is preferably transparent to the wavelength of interest in the endpoint monitoring system 12 (FIG. 1).

The polishing composition distribution layer 130 may also be made of a wide variety of polymeric materials, and polyurethanes, polyethylenes and combinations thereof are particularly useful. The polyurethanes and polyethylenes are preferably foamed to provide a positive pressure directed toward to substrate during polishing operations when the layer 130 is compressed. Foamed materials with open cells are preferred. In some embodiments, the layer 130 has between about 10 and about 90 percent porosity, and can optionally be fastened to the guide plate 132 by a layer of a preferably transparent adhesive, or a double sided tape (not shown in FIG. 2). In an alternative embodiment, the polishing composition layer 130 is made of a hydrogel material, such as, for example a hydrophilic urethane, that can absorb water in a range of about 5 to about 60 percent by weight to provide a lubricious surface during polishing operations.

The polishing composition distribution layer 130 substantially uniformly distributes a polishing composition across the substrate surface, which provides more uniform polishing operations. The polishing composition distribution layer 130 may optionally include flow resistant elements such as baffles, grooves (not shown in FIG. 2), or pores, to regulate the flow rate of the polishing composition during polishing operations. In some embodiments, the layer 130 can include various layers of different materials to achieve desired polishing composition flow rates at varying depths from the surface 160. For example, a surface layer at the polishing surface 160 may have larger pores to increase the amount and rate of a slurry flow on the surface 160 while a lower layer adjacent the guide plate 132 has smaller pores to keep more slurry near the surface 160 layer and more precisely regulate slurry flow.

The support layer 140 may be made of a wide variety of materials, and is preferably fluid impermeable (although permeable materials may be used in combination with an optional membrane layer 145). The support layer 140 can be incompressible, such as a rigid frame or a housing, but is preferably compressible to provide a positive pressure directed toward the polishing surface 160. The support layer 140 is preferably made of a polymeric material, foamed polymers are preferred, and foamed materials with closed cells are particularly preferred. Polyurethanes have been found to be particularly useful. Suitable polyurethanes include, for example, those available under the trade designation PORON from Rogers Corp., Rogers, Conn., as well as those available under the trade designation PELLETHANE from Dow Chemical, Midland, Mich., particularly PELLETHANE 2102-65D. Other suitable materials include polyethylene terepthalates (PET), such as, for example biaxially oriented PET widely available under the trade designation MYLAR, as well as bonded rubber sheets available from Rubberite Cypress Sponge Rubber Products, Inc., Santa Ana, Calif., under the trade designation BONDTEX. The support layer 140 can optionally be fastened to the guide plate by a layer of adhesive, preferably a transparent adhesive, or a double sided tape.

Referring again to FIG. 3, the polishing pad 215 includes a region 292 that provides a path 290 through the thickness of the pad 215 (e.g. generally normal to the surface 260 of the polishing pad). As discussed in detail below, the region 292 may be free of polishing elements 235, or may include transparent polishing elements 235.

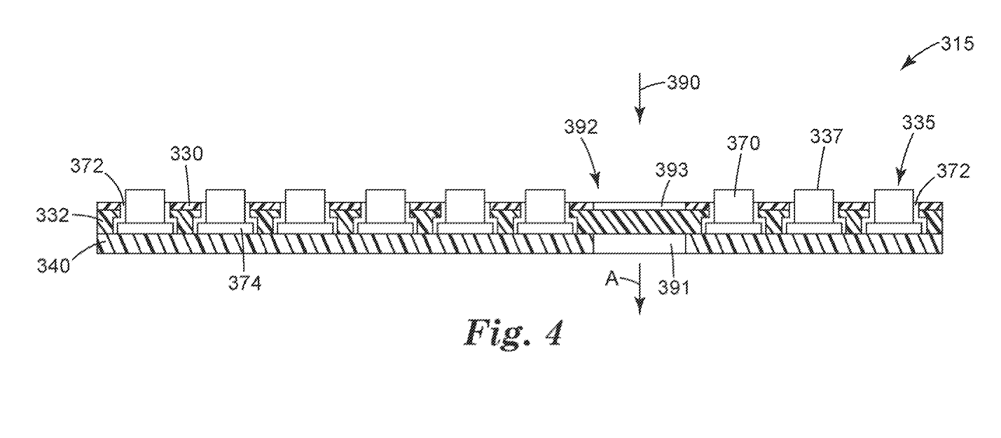

In an embodiment illustrated in FIG. 4, a polishing pad 315 includes a polishing composition distribution layer 330, a guide plate 332, and a support layer 340. The polishing composition distribution layer 330 and the guide plate 332 are collectively substantially transparent to energy or fields in the range of wavelength(s) of interest utilized by the endpoint monitoring system 12 (FIG. 1). In some embodiments, the polishing composition distribution layer 330 and/or the guide plate 332 can be made of a transparent polymeric material.

The guide plate 332 includes plurality of apertures 372 each retaining a polishing element 335. Each polishing element 335 includes an elongate body 370, a retaining flange 374, and a polishing tip 337.

In this embodiment a region 392 of the polishing pad 315 is free of polishing elements 335. In the region 392 a path 390 through the thickness of the polishing pad 315 (substantially normal to a plane of a major surface of the polishing pad 315 and along direction A) includes an aperture 391 in the support layer 340.

In any of the embodiments described in this application, the polishing composition distribution layer 330 may optionally include an aperture (See, for example, aperture 392 in FIG. 4) that overlies and/or is substantially aligned with an aperture (e.g. 391 in FIG. 4) in the support layer 340.

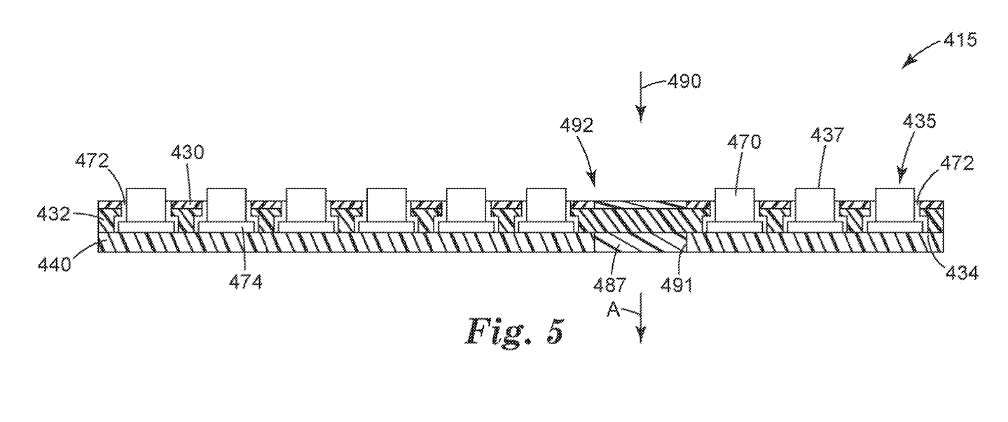

In an embodiment illustrated in FIG. 5, a polishing pad 415 includes a polishing composition distribution layer 430, a guide plate 432, and a support layer 440. The polishing composition distribution layer 430 and the guide plate 432 are collectively substantially transparent to energy or fields in the range of wavelength(s) of interest utilized by the endpoint monitoring system 12 (FIG. 1). In some embodiments, the polishing composition distribution layer 430 and/or the guide plate 432 can be made of a transparent polymeric material.

The guide plate 432 includes plurality of apertures 472 each retaining a polishing element 435. Each polishing element 435 includes an elongate body 470, a retaining flange 474, and a polishing tip 437.

In this embodiment a region 492 of the polishing pad 415 is free of polishing elements 435. In the region 492 an optical path 490 through the thickness of the polishing pad 415 (substantially normal to a plane of a major surface of the polishing pad 415 and along direction A) includes an aperture 491 in the support layer 440. In this embodiment the aperture 491 includes a transparent member (e.g. a plug) 487. The transparent member 487 may be affixed to the second side of the guide plate 432, preferably a second major surface 434 of the guide plate 432, with any suitable transparent adhesive or adhesively backed tape. In some embodiments, a cure in place transparent adhesive may be used.

For example, the transparent member 487 can be formed of one or more polymeric materials, such as, a polyurethane or a halogenated polymer (e.g., polychlorotrifluoroethylene (PCTFE), perfluoroalkoxy (PFA), fluorinated ethylene propylene (FEP), or polytetra-fluoroethylene (PTFE)).

The transparent member 487 is substantially transparent to energy in the range of wavelength(s) of interest utilized by the endpoint detection apparatus 12 (FIG. 1). In certain embodiments, at least about 25% (e.g., at least about 35%, at least about 50%, at least about 60%, at least about 70%, at least about 80%, at least about 90%, at least about 95%) of energy at a wavelength of interest that impinges upon the transparent member 487 is transmitted therethrough.

For example, the transparent member 487 can be made of a material with a refractive index of about 1.48 or less (e.g., about 1.45 or less, about 1.4 or less, about 1.35 or less, about the same as the refractive index of water), which can reduce reflections at interfaces along an optical path 490 and improve the signal to noise ratio of the endpoint detection apparatus. In some embodiments, the transparent member 487 can be formed of a highly optically isotropic polymer, which can help maintain the polarization of the interrogating energy beam from the endpoint detection apparatus.

In certain implementations, surfaces of the transparent member 487 can also optionally be roughened to improve adhesion to the guide plate 432, or to alter the interference of light beams traveling through them.

In some embodiments, the polishing composition distribution layer 430 may include an aperture (not shown in FIG. 4) that overlies the aperture 491 in the support layer 440.

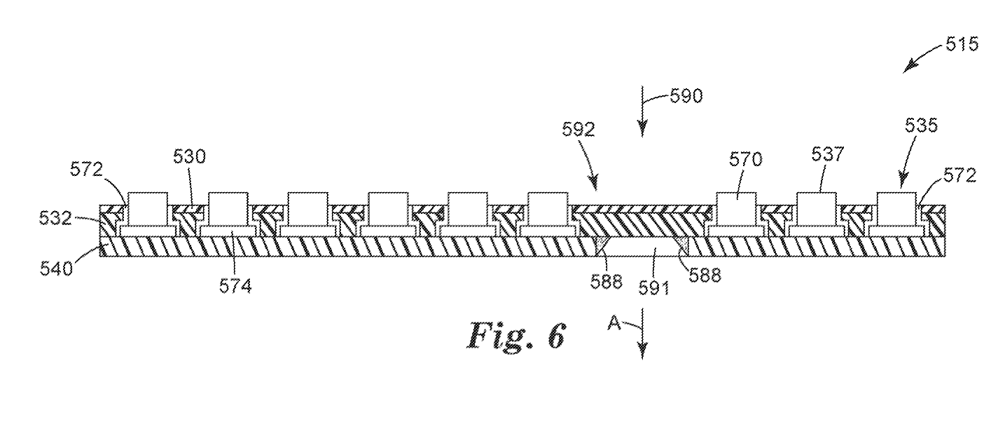

In an embodiment illustrated in FIG. 6, a polishing pad 515 includes a polishing composition distribution layer 530, a guide plate 532, and a support layer 540. The polishing composition distribution layer 530 and the guide plate 532 are collectively substantially transparent to energy or fields in the range of wavelength(s) of interest utilized by the endpoint monitoring system 12 (FIG. 1). In some embodiments, the polishing composition distribution layer 530 and/or the guide plate 532 can be made of a transparent polymeric material.

The guide plate 532 includes plurality of apertures 572 each retaining a polishing element 535. Each polishing element 535 includes an elongate body 570, a retaining flange 574, and a polishing tip 537.

In this embodiment a region 592 of the polishing pad 515 is free of polishing elements 535. In the region 592 an optical path 590 through the thickness of the polishing pad 515 (substantially normal to a plane of the major surface of the polishing pad 515 and along direction A) includes an aperture 591 in the support layer 540. It can be useful, particularly if the support layer 540 is made of a foamed or other porous material, to at least partially seal the foam in the walls of the aperture 591 with an adhesive 588. The adhesive 588 preferably seals at interfaces between the guide plate 532 and the support layer 540 within the aperture 591, as well as along the exposed walls of the support layer 540 in the aperture 591. A substantially continuous bead of adhesive 588 can substantially eliminate migration of liquid polishing compositions that can interfere with the operation of the endpoint apparatus. Any suitable adhesive 588 may be used, and rapidly curable, moisture resistant adhesives are preferred, and transparent adhesives of these types are particularly preferred.

In some embodiments, the polishing composition distribution layer 530 may include an aperture (not shown in FIG. 5) that overlies the aperture 591 in the support layer 540.

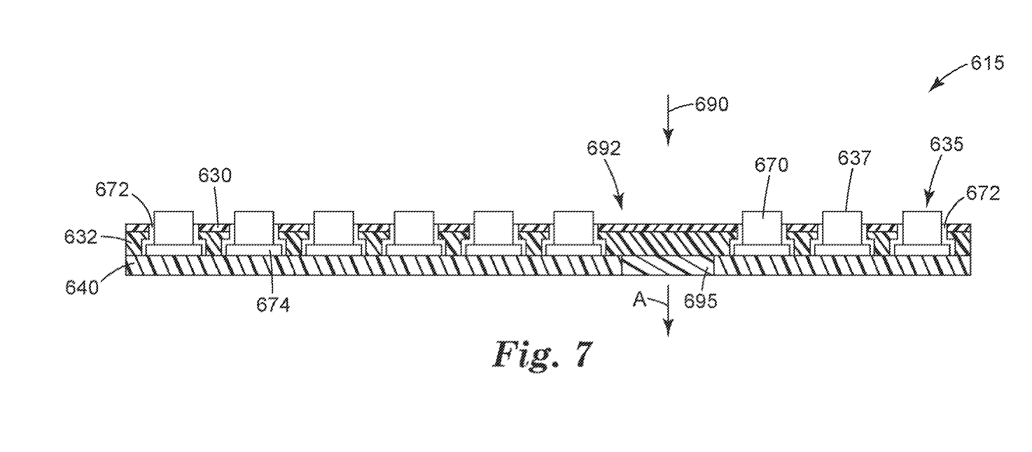

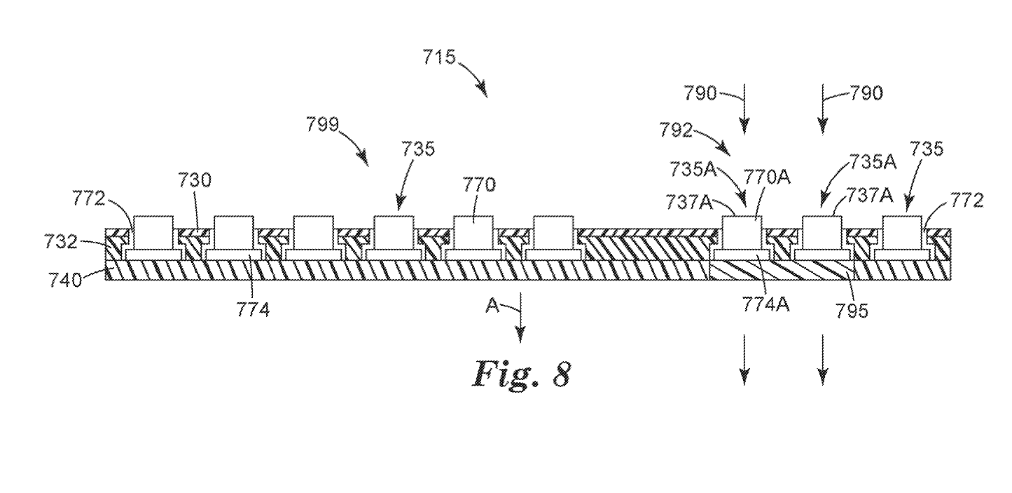

In yet another embodiment illustrated in FIG. 7, a polishing pad 615 includes a polishing composition distribution layer 630, a guide plate 632, and a support layer 640. The polishing composition distribution layer 630 and the guide plate 632 are collectively substantially transparent to energy or fields in the range of wavelength(s) of interest utilized by the endpoint monitoring system 12 (FIG. 1). In some embodiments, the polishing composition distribution layer 630 and/or the guide plate 632 can be made of a transparent polymeric material.

The guide plate 632 includes plurality of apertures 672, each retaining a polishing element 635. Each polishing element 635 includes an elongate body 670, a retaining flange 674, and a polishing tip 637.

In this embodiment a region 692 of the polishing pad 615 is free of polishing elements 635. The region 692 overlies and is at least partially aligned with a region 695 of the support layer 640. The region 695, which may be made of a material that is the same or different from the remainder of the support layer 640, is substantially transparent to energy in the range of wavelength(s) of interest utilized by the endpoint detection apparatus 12 (FIG. 1). In certain embodiments, at least about 25% (e.g., at least about 35%, at least about 50%, at least about 60%, at least about 70%, at least about 80%, at least about 90%, at least about 95%) of energy at a wavelength of interest that impinges upon the region 695 is transmitted therethrough.

For example, the region 695 may be transparent, or may be made transparent by applying heat and/or pressure to the material, or a transparent material may be cast in place in an aperture suitably positioned in the support layer 640 (i.e. underlying the region 692). In an alternative embodiment, the entire support layer 640 may be made of a material that is or may be made transparent to energy in the range of wavelength(s) of interest utilized by the endpoint detection apparatus. Preferred transparent materials for the layer 640 and the region 695 include, for example, polyurethanes.

In some embodiments, the polishing composition distribution layer 630 may include an aperture (not shown in FIG. 6) that overlies the region 695 in the support layer 640.

In yet another embodiment illustrated in FIG. 8, a polishing pad 715 includes a polishing composition distribution layer 730 and a guide plate 732, each of which may optionally be made of transparent materials, as well as a support layer 740. In a first region 799 of the polishing pad 715, the guide plate 732 includes plurality of apertures 772, each retaining a polishing element 735. Each polishing element 735 includes an elongate body 770, a retaining flange 774, and a polishing tip 737.

A second region 792 of the polishing pad 715, different from the first region 799, includes at least one transparent polishing element 735A. In the region 792 an optical path 790 through the thickness of the polishing pad 715 (substantially normal to a plane of the major surface of the polishing pad 715 and along direction A) traverses at least one transparent polishing element 735A, which overlies and is at least partially aligned with a region 795 of the support layer 740. The region 795, which may be made of a material that is the same or different from the remainder of the support layer 740, is substantially transparent to energy in the range of wavelength(s) of interest utilized by the endpoint detection apparatus 12 (FIG. 1). In certain embodiments, at least about 25% (e.g., at least about 35%, at least about 50%, at least about 60%, at least about 70%, at least about 80%, at least about 90%, at least about 95%) of energy at a wavelength of interest that impinges upon the region 695 is transmitted therethrough.

For example, the region 795 may be made transparent by applying heat and/or pressure to the material, or a transparent material may be cast in place in an aperture in the support layer 740. In an alternative embodiment, the entire support layer 740 may be made of a material that is or can be made transparent to energy in the range of wavelength(s) of interest utilized by the endpoint detection apparatus. Preferred transparent materials for the layer 740 and the region 795 include, for example, polyurethanes.

In the embodiment shown in FIG. 8, the size of the region 792 that includes the transparent polishing elements 735A may vary widely depending on the intended application. The polishing pad 715 may include a single transparent polishing element 735A, a relatively small number of transparent polishing elements 735A, or only transparent polishing elements 735A. Polishing pads 715 with only transparent polishing elements are generally less expensive to manufacture, and for at least this reason are preferred over pads including mixtures of transparent and opaque polishing elements.

Referring again to FIG. 2, the polishing pads 115 described herein are relatively inexpensive to manufacture. Suitable manufacturing processes are described in U.S. Patent Application No. 60/926,244, which is incorporated herein by reference in its entirety. A brief discussion of an exemplary manufacturing process is described herein, which is not intended to be limiting. For example, the guide plate 132 may be made by laminating both sides of a sheet of a suitable relatively rigid polymeric material, such as a polycarbonate, with an adhesive. The adhesive layers may be used to bond an appropriate polishing composition distribution layer 130, and then an array of apertures may then be created (for example, by drilling) in the sheet to form the bores 170 and the undercut regions 174.

The polishing elements 135 are preferably injection molded, and may then be applied to the drilled sheet. Since the polishing elements 135 include flanges 174, gravity pulls the elements 135 into position in the bores 170 in the guide plate 132.

A support layer 140 may then be laminated onto the resulting construction to form a completed polishing pad.

The present disclosure is further directed to a method in which a monitoring signal emitted by a monitoring system in a chemical mechanical polishing apparatus is transmitted through a thickness of a polishing pad to a detector to monitor an endpoint in a polishing operation. The polishing pads described in FIGS. 2-8 above include a transparent region in the support layer and a first region in the polishing composition distribution layer at least partially aligned with the transparent region. The first region in the polishing composition distribution layer includes one of: a region free of polishing elements or a region with at least one transparent polishing element. The monitoring signal can be transmitted through the thickness of the polishing pad via the first region in the polishing composition distribution layer and the transparent region in the support layer.

The polishing pads described in the present disclosure will now be illustrated with reference to the following non-limiting example.

### EXAMPLE

Optical endpoint signal tests were performed using the polishing pads described herein, and the results were compared to commercially available polishing pads available from Applied Materials, Inc., Santa Clara, Calif., under the trade designation Mirra.

200 mm silicon wafers were deposited with 5000 Å silicon dioxide followed by 250 Å tantalum nitride (TaN) and a thin copper layer followed by 15,000 Å electroplated copper films.

During processing, polish pressure of 2 pounds per square inch (Psi) (about 13,800 N/m2) was applied to the wafers and the pad table was rotated at 100 rpm. Commercially available copper removal slurry from Paulmark International, Inc., Taipei, Taiwan, was supplied at 150 ml/min.

Initial signal intensity was high due to high reflectivity of the copper surface, but as the copper surface was removed to expose barrier material, in this case, TaN, surface reflectivity was reduced and a drop in signal intensity was observed. This decrease in reflectivity was used to determine the end of the copper polish process.

The polishing pads were tested for signal integrity and signal magnitude, and the signal intensity change observed on the tool at location 1 was about 10-12 units for the conventional pad. The polishing pads described herein in FIGS. 4 and 8 each registered a signal intensity change at a level of about 8-12 units at location 1 on the tool. These results indicate that the optical paths in the presently described polishing pads have signal transmission characteristics that are similar to the transmission characteristics of the commercially available polishing pads

Various embodiments of the invention have been described. These and other embodiments are within the scope of the following claims.

1. A polishing pad comprising a polishing composition distribution layer on a first side of a guide plate and a support layer on an opposed second side of a guide plate, wherein the guide plate retains a plurality of polishing elements that extend along a first direction substantially normal to a plane including the polishing pad and through the polishing composition distribution layer, wherein the polishing pad comprises an optical path along the first direction and through a thickness of the pad for transmitting a signal for in situ monitoring of an endpoint in a polishing operation.

2. The polishing pad of claim 1, wherein the optical path comprises a first region in the polishing composition distribution layer free of polishing elements and a transparent region in the support layer, wherein the transparent region is substantially aligned along the first direction with the first region.

3. The polishing pad of claim 2, wherein the transparent region comprises an aperture in the support layer.

4. The polishing pad of claim 3, wherein the polishing composition distribution layer comprises an aperture overlying the aperture in the support layer.

5. The polishing pad of claim 3, further comprising a transparent member in the aperture in the support layer, wherein the transparent member is adjacent to the second side of the guide plate.

6. The polishing pad of claim 5, further comprising a layer of adhesive between the transparent member and a major surface of the guide plate.

7. The polishing pad of claim 3, further comprising an adhesive on at least a portion of an exposed wall of the aperture in the support layer.

8. The polishing pad of claim 3, further comprising an adhesive at an interface between the support layer and the guide plate.

9. The polishing pad of claim 1, wherein the guide plate is transparent.

10. The polishing pad of claim 2, wherein the transparent region in the support layer comprises a transparent polymer.

11. The polishing pad of claim 2, wherein the entire support layer comprises a transparent polymer.

12. The polishing pad of claim 1, wherein the guide plate comprises a transparent polymer.

13. The polishing pad of claim 1, wherein the polishing elements comprise elongate cylinders, and wherein a longitudinal axis of the cylinders is along the first direction.

14. The polishing pad of claim 13, wherein the polishing elements comprise a flange, and wherein the flange engages the guide plate.

15. The polishing pad of claim 1, wherein the polishing elements have a hollow body.

16. The polishing pad of claim 1, wherein the guide plate comprises an array of apertures, and wherein at least a portion of the apertures comprise a main bore and an undercut region, and wherein the undercut region forms a shoulder that retains a flange on a polishing element.

17. A polishing pad comprising
a polishing composition distribution layer comprising a plurality of polishing elements, wherein the polishing elements extend upwardly through the polishing composition distribution layer, and wherein the polishing composition distribution layer comprises a first region comprising at least one transparent polishing element; and
a support layer comprising a transparent region underlying the first region.

18. The polishing pad of claim 17, wherein the guide plate is transparent.

19. The polishing pad of claim 17, wherein the transparent region in the support layer comprises a transparent polymer.

20. The polishing pad of claim 17, wherein the entire support layer comprises a transparent polymer.

21. A chemical mechanical polishing system, comprising:
a platen;
the polishing pad of claim 17 on the platen; and
a monitoring system to monitor a polishing operation, wherein the monitoring system emits a monitoring signal to a detector through the first region and the transparent region.

22. A method comprising polishing a workpiece with the polishing pads of claim 1 or 17.
